(19) United States
(12) Patent Application Publication
(10) Pub. No.: US 2008/0165513 A1
(43) Pub. Date: Jul. 10, 2008

(54) Electronic component built-in substrate and method for manufacturing the same

(75) Inventors: Akinobu Inoue, Nagano (JP); Sadakazu Akaike, Nagano (JP); Atsunori Kajiki, Nagano (JP); Yuya Yoshino, Nagano (JP); Takashi Tsubota, Nagano (JP); Norio Yamanishi, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 12/000,731

(22) Filed: Dec. 17, 2007

(30) Foreign Application Priority Data
Dec. 19, 2006 (JP) P.2006-341666

(51) Int. Cl. H05K 1/18; H05K 3/30

(52) U.S. Cl. 361/761; 29/841

(57) ABSTRACT

It is an electronic component built-in substrate 100 configured as follows. That is, an electronic component 30 is provided between at least two boards 10 and 20. An electrode 34 of the electronic component 30 is electrically connected to at least one of the board 10. Also, the boards 10 and 20 are electrically connected to each other. Additionally, the gap between the boards 10 and 20 is sealed with a resin. The electronic component built-in substrate 100 is featured in that a solder ball 40 for electrically connecting the boards 10 and 20 to each other is provided on a surface of the electronic component 30, which faces the other board 20.

### BACKGROUND OF THE INVENTION

1. Technical Field

The present invention relates to an electronic component built-in substrate and to a method for manufacturing an electronic component built-in substrate. More particularly, the invention relates to an electronic component built-in substrate capable of reducing the height and the planar dimension thereof and enhancing the reliability of the electrical connection between an electronic component and a wiring board, and also relates to a method for manufacturing such an electronic component built-in substrate.

2. Related Art

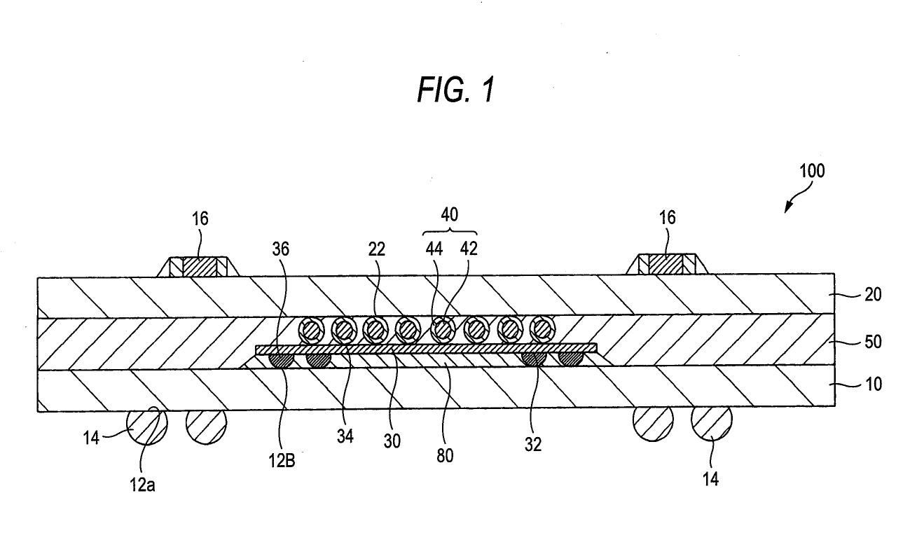

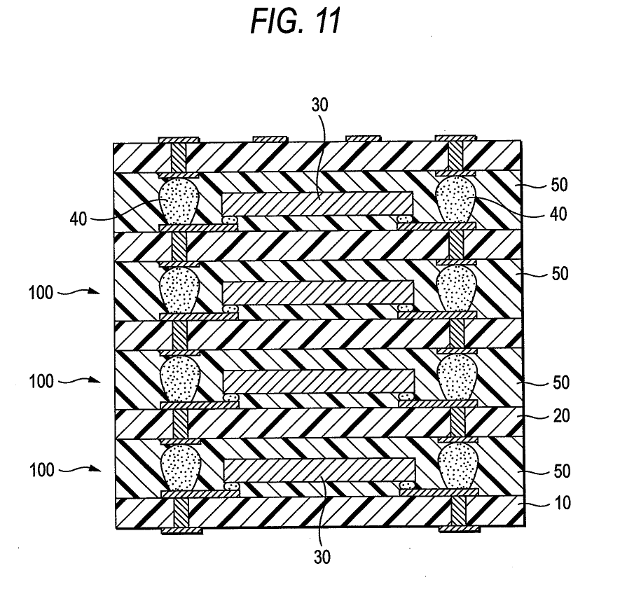

With the enhancement of the performance of electronic apparatuses, electronic component built-in substrates, on each of which electronic components are densely mounted, have been developed. Some of such electronic component built-in substrates are configured so that electronic components are mounted between wiring boards as illustrated in FIG. 11, and that the gap between the wiring boards is sealed with a resin (see, for example, FIG. 1 of Patent Document 1).

### [Patent Document 1] JP-A-2003-347722

### DISCLOSURE OF THE INVENTION

### Problems to be Solved by the Invention

As exemplified by an electronic component built-in substrate 100 shown in FIG. 11, each of solder balls 40 provided at the outside of each electronic component 30 has a large diameter dimension so as to electrically connect the top surface of an associated lower layer side wiring board 10 to the bottom surface of an associated upper layer side wiring board 20 separated by a clearance therefrom. In the case of using the solder balls 40 having such large diameter dimensions, the provision pitch of the solders 40 is wide. This causes the following problems. That is, an area needed for installing the necessary number of solder balls 40 is large. The planar dimension (i.e., the plane area) of the electronic component built-in substrate 100 is large.

Additionally, in a case where the diameter dimensions of the solder balls 40 are large, another problem of increase in the thickness dimension of the electronic component built-in substrate 100 occurs.

As described above, in a case where the diameter dimensions of the solder balls 40 for electrically connecting the lower layer side wiring board 10 to the upper layer side wiring board 20 are large, there is another problem in that the miniaturization of the electronic component built-in substrate 100 is restricted.

### SUMMARY OF THE INVENTION

Accordingly, an object of the invention is to provide an electronic component built-in substrate being capable of considerably reducing the planar dimension (i.e., the plane area) and the height dimension thereof, and to provide a method for such an electronic component built-in substrate.

### Means for Solving the Problems

To achieve the foregoing object, according to a first aspect of the invention, there is provided an electronic component built-in substrate including:

at least two wiring boards,

an electronic component provided between the two wiring boards,

an electrode of the electronic component,

the electrode being electrically connected to at least one of the wiring boards, the wiring boards being electrically connected to each other, and a gap between the wiring boards being sealed with a resin, and

a solder ball for electrically connecting the wiring boards to each other, the solder ball being provided on a surface of the electronic component which faces the other wiring board.

According to a second aspect of the invention, there is provided the electronic component built-in substrate according to the first aspect, wherein

the solder ball is a core-contained solder ball formed by coating an outer surface of a metal sphere with solder.

According to a third aspect of the invention, there is provided the electronic component built-in substrate according to the first aspect, wherein

the solder ball is a copper-contained solder ball formed by coating an outer surface of a sphere made of copper material with solder.

Thus, the electrical connection between the lower layer side wiring board and the upper layer side wiring board can surely be achieved. Additionally, the solder balls each of which contains a sphere made of a metal or a copper material as a core. Consequently, even after the solder balls are reflowed, the cores are left, so that the clearance between the lower layer side wiring board and the upper layer side wiring board can surely be maintained at a constant value. That is, regardless of a thin-wall structure, a high-flatness electronic component built-in substrate can be provided.

According to a forth aspect of the invention, there is provided the electronic component built-in substrate according to any one of the first to third aspects, wherein

a plurality of the electronic components are provided between the wiring boards.

Consequently, amore compact highly-functional electronic component built-in substrate can be provided.

According to a fifth aspect of the invention, there is provided the electronic component built-in substrate according to any one of the first to forth aspects, wherein

at least one of electrodes of such an electronic component is wire-bonded to the one of the wiring boards.

Further, according to a sixth aspect of the invention, there is provided the electronic component built-in substrate according to the fifth aspect, wherein

at least the wire-bonded electrode in the electrodes of the electronic component is coated with a protection material.

Preferably, according to a seventh aspect of the invention, there is provided the electronic component built-in substrate according to the sixth aspect, wherein

the protection material is coated on at least the electrode of the electronic component in a state in which a bonding wire connection portion at the side of the wiring board and a part of an upper-side portion of a wire loop formed of the bonding wire are exposed.

Consequently, the reliability of the electrical connection between the electrodes of the electronic component and the boards can be enhanced. The miniaturization of the electronic component built-in substrate is expedited by limiting the portion coated with the protection material.

According to an eighth aspect of the invention, there is provided a method for manufacturing an electronic component built-in substrate wherein an electronic component is mounted between a first wiring board and a second wiring board, the first wiring board and the second wiring board are electrically connected to each other, and a seal resin is injected into a gap between the first wiring board and the second wiring board,

the method including the steps of:

positioning and mounting the electronic component provided with a plurality of electrodes on one surface of the first wiring board, and electrically connecting a first electrode of the electronic component to the first wiring board,

connecting a solder ball to a second electrode of the electronic component,

opposing one surface of the second wiring board to the solder ball connected to the second electrode of the electronic component, and arranging the second wiring board on the first wiring board,

electrically connecting the second wiring board to the electronic component by reflowing the solder balls to electrically connect the first wiring board to the second wiring board through the electronic component, and

injecting a seal resin into a gap between the first wiring board and the second wiring board.

According to a ninth aspect of the invention, there is provided a method for manufacturing an electronic component built-in substrate wherein an electronic component is mounted between a first wiring board and a second wiring board, the first wiring board and the second wiring board are electrically connected to each other, and a seal resin is injected into a gap between the first wiring board and the second wiring board,

the method including the steps of:

positioning and mounting the electronic component provided with a plurality of electrodes on one surface of the first wiring board, and electrically connecting a first electrode of the electronic component to the first wiring board,

connecting a solder ball to one surface of the second wiring board,

opposing one surface of the second wiring board to the solder ball connected to the second electrode of the electronic component, and arranging the second wiring board on the first wiring board,

electrically connecting the second wiring board to the electronic component by reflowing the solder balls to electrically connect the first wiring board to the second wiring board through the electronic component, and

injecting a seal resin into a gap between the first wiring board and the second wiring board.

According to a tenth aspect of the invention, there is provided the method for manufacturing an electronic component built-in substrate according to the eighth or ninth aspect, wherein

as the solder ball, a core-contained solder ball formed by coating an outer surface of a metal spherical core member with solder is used.

More specifically, according to an eleventh aspect of the invention, there is provided the method for manufacturing an electronic component built-in substrate according to the eighth or ninth aspect, wherein

as the solder ball, a core-contained solder ball formed by coating an outer surface of a copper spherical core member with solder is used.

Consequently, the clearance between the wiring boards can be maintained at a constant value. Accordingly, the mechanical strength of the electronic component built-in substrate can be enhanced.

According to a twelfth aspect of the invention, there is provided the method for manufacturing an electronic component built-in substrate according to any one of the eighth to eleventh aspects, wherein

the first electrode like a bump is formed on one surface of the electronic component, while the second electrode is formed on another surface of the electronic component, and

the first electrode is electrically connected to the first wiring board by a flip chip method using the first electrode.

According to a thirteenth aspect of the invention, there is provided the method for manufacturing an electronic component built-in substrate according to any one of the eighth to eleventh aspects, wherein

the first electrode and the second electrode of the electronic component are formed on the same surface thereof, and

the step of electrically connecting the first electrode to the first wiring board is performed by a wire bonding connection.

### EFFECTS OF THE INVENTION

In accordance with an electronic component built-in substrate and a method for manufacturing an electronic component built-in substrate according to the invention, a solder ball is placed on a surface of an electronic component provided between first and second wiring boards. This surface is opposed to the second wiring board and has hitherto been not particularly utilized. Consequently, the diameter dimension of the solder ball for electrically connecting the first wiring board and the second wiring board to each other can be considerably reduced. Also, the plane area and the height of the electronic component built-in substrate can be largely reduced. Additionally, a small electronic component built-in substrate can be provided at low cost.

### BRIEF DESCRIPTION OF THE DRAWINGS

### Brief Description of the Drawings

FIG. 1 is a transverse cross-sectional view illustrating a structure of an electronic component built-in substrate according to a first embodiment of the invention.

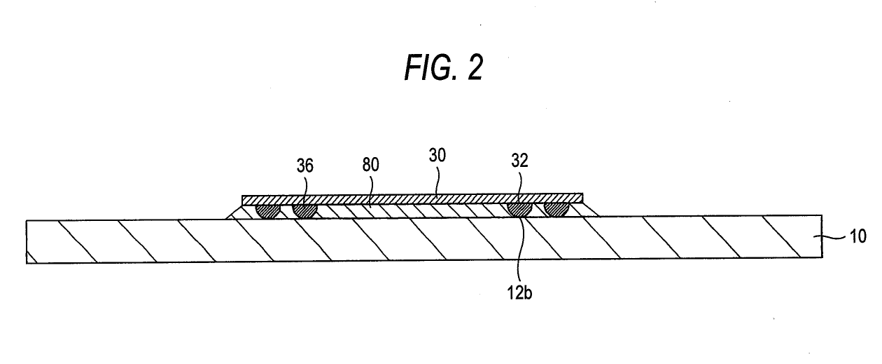

FIG. 2 is a transverse cross-sectional view illustrating a state of the electronic component built-in substrate in a step of a manufacturing process thereof.

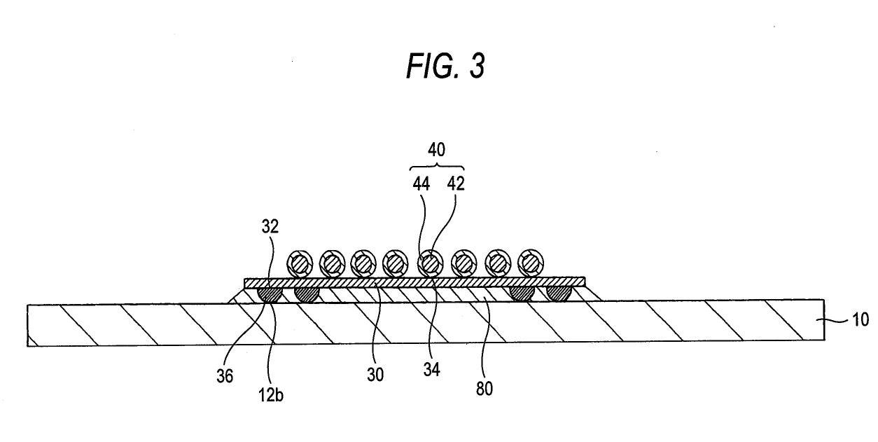

FIG. 3 is a transverse cross-sectional view illustrating a state of the electronic component built-in substrate in a step of the manufacturing process thereof.

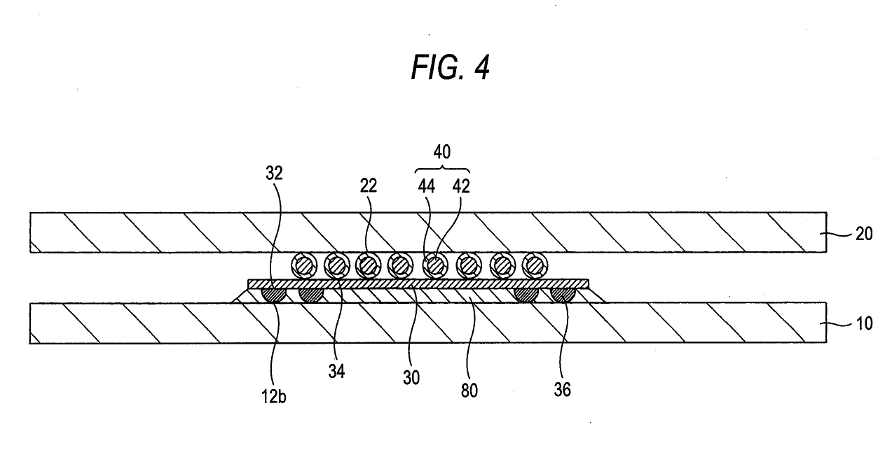

FIG. 4 is a transverse cross-sectional view illustrating a state of the electronic component built-in substrate in a step of the manufacturing process thereof.

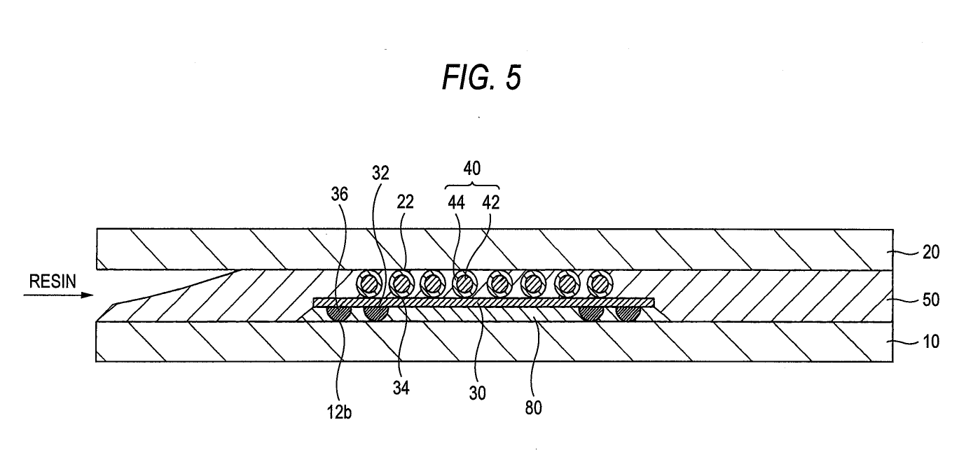

FIG. 5 is a transverse cross-sectional view illustrating a state of the electronic component built-in substrate in a step of the manufacturing process thereof.

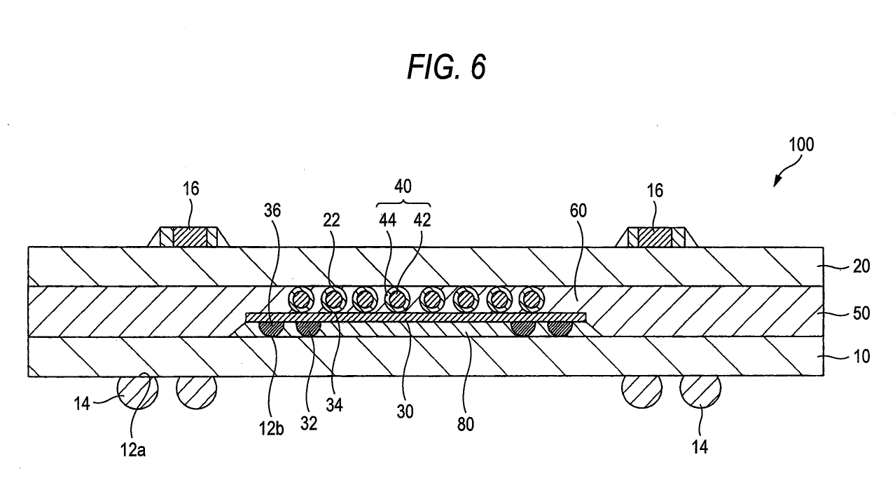

FIG. 6 is a transverse cross-sectional view illustrating a state of the electronic component built-in substrate in a step of the manufacturing process thereof.

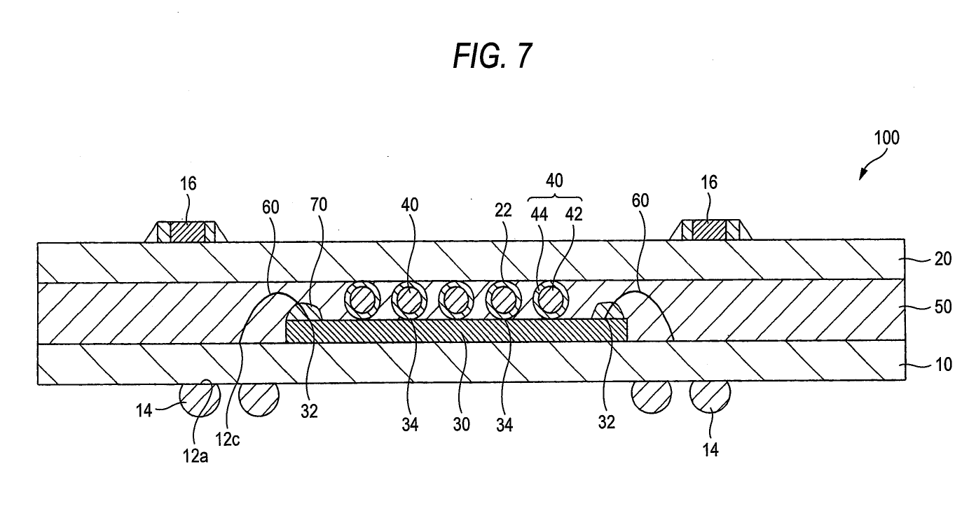

FIG. 7 is a transverse cross-sectional view illustrating a structure of an electronic component built-in substrate according to a second embodiment of the invention.

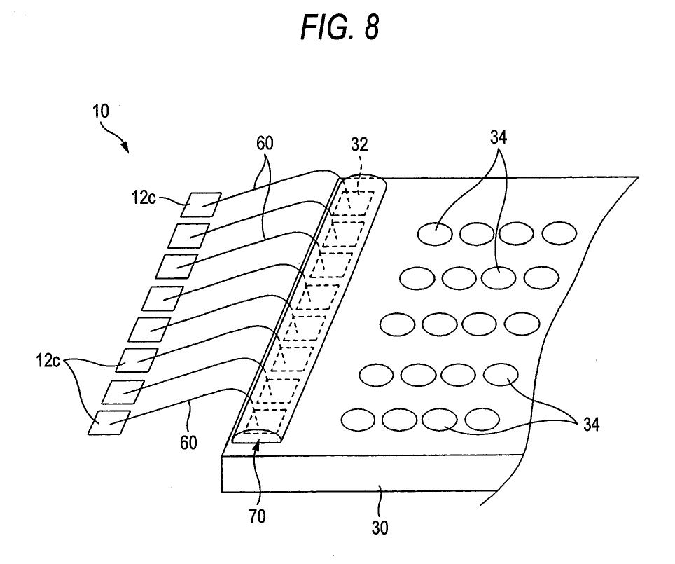

FIG. 8 is a schematic view illustrating a wire-bonding portion between an electronic component and the substrate.

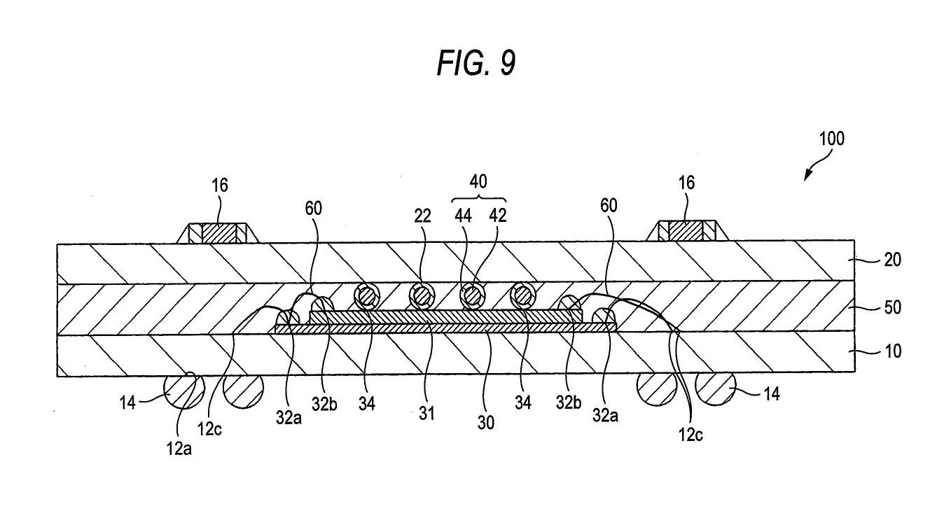

FIG. 9 is a transverse cross-sectional view illustrating a structure of an electronic component built-in substrate according to a third embodiment of the invention.

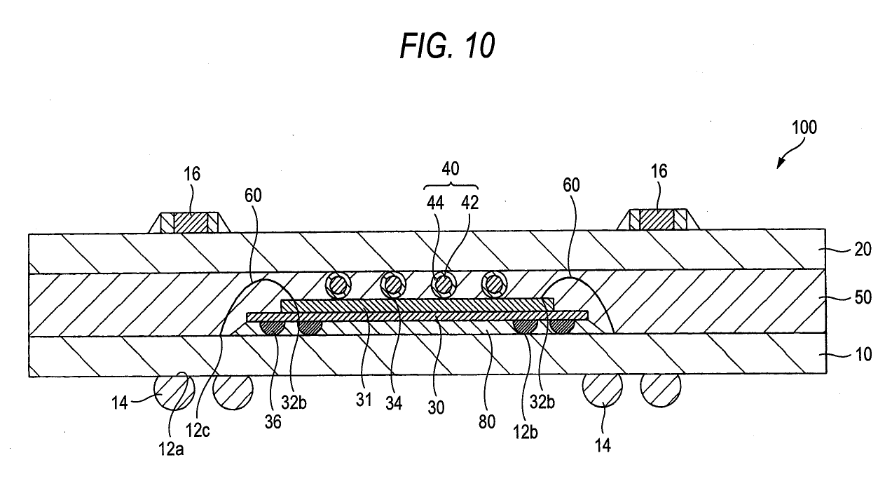

FIG. 10 is a transverse cross-sectional view illustrating a structure of an electronic component built-in substrate according to a fourth embodiment of the invention.

FIG. 11 is a transverse cross-sectional view illustrating an example of a related electronic component built-in substrate.

### DETAILED DESCRIPTION OF THE PREFERRED EMBODIMENTS

### Best Mode for Carrying Out the Invention

### First Embodiment

Hereinafter, an embodiment of the electronic component built-in substrate according to the invention is described below with reference to the accompanying drawings. FIG. 1 is a transverse cross-sectional view illustrating a structure of an electronic component built-in substrate according to a first embodiment of the invention.

As illustrated in FIG. 1, an electronic component built-in substrate 100 according to the present embodiment is configured so that electronic components 30 are mounted between two wiring boards 10 and 20, that a lower layer side wiring board 10 serving as a first wiring board is electrically connected to an upper layer side wiring board 20 by solder balls 40. A seal resin 50 is injected into a gap between the lower layer side wiring board 10 and the upper layer side wiring board 20. Incidentally, in this figure, the indication of wiring formed on each of the wiring boards 10 and 20 is omitted.

A bump 14 serving as an external connection terminal, which is exemplified by solder, is provided on the bottom surface of the lower layer side board 10. Connection portions 12a and 12b formed by exposing a part of the wiring from a protection coat are provided on the bottom surface and the top surface of the lower layer side wiring board 10, respectively. A part of the connection portion 12b formed on the top surface of the lower layer side wiring board 10 and the bump 14 formed on the bottom surface of the lower layer side wiring board 10 are electrically connected to each other.

On the other hand, the connection portion 22 formed by exposing a part of the wiring from the protection coat is provided on the bottom surface of the upper layer side wiring board 20. Circuit parts 16, such as chip capacitors, resistors, and inductors, are mounted on the top surface of the upper layer side wiring board 20. The circuit parts 16 are attached to the wiring formed on the top surface of the upper layer side wiring board 20 by soldering.

In the case of additionally connecting another electronic component built-in substrate 100 onto the top side of the upper layer side wiring board 20, a connection portion (not shown) formed by exposing a part of the wiring from the protection coat can be provided on the top surface of the upper layer side wiring board 20. In this case, the upper layer side wiring board 20 is electrically connected thereto by connection portions formed on the top surface and the bottom surface thereof, respectively.

A semiconductor element 30 serving as an electronic component is mounted on the top surface of the lower layer side wiring board 10. The semiconductor element 30 is electrically connected to the connection portion 12b of the lower layer side wiring board 10 by a flip-chip connection through a flip-chip connection bump 36 attached to a first electrode 32 formed on one side surface (i.e., an active surface) of the semiconductor element 30. An underfill resin 80 is injected into a gap between the top surface of the lower layer side wiring board 10 and the bottom surface of the semiconductor element 30.

The solder balls 40 for electrically connecting the lower layer side wiring board 10 to the upper layer side wiring board 20 are provided on the top surface (i.e., a surface facing the upper layer side wiring board 20) of the semiconductor element 30. The solder balls 40 are put on a solder ball electrode 34 serving as a second electrode formed on a surface facing a surface, on which a first electrode 32 is formed, of the semiconductor element 30. A part of the first electrode 32 is electrically connected to a part of the solder ball electrode 34.

Solder balls formed by coating outer surfaces of copper cores 42, which are made of copper materials and are shaped like spheres, with solder 44 are used as the solder balls 40 of the present embodiment. For convenience of description, in this figure, solder balls 40, which are in a state before reflowed, are illustrated as reflowed solder balls 40.

It is sufficient for the solder balls 40 to electrically connect the top surface of the semiconductor element 30 to the bottom surface of the upper layer side wiring board 20, between which there is a clearance. Accordingly, it is sufficient that the diameter dimension of each of copper cores 42 contained in the solder balls 40 is equal to the clearance between the height positions of the top surface of the semiconductor element 30 and the bottom surface of the upper layer side wiring board 20. That is, the diameter dimension of the solder ball 40 can considerably be reduced.

The lower layer side wiring board 10 and the upper layer side wiring board 20 are electrically connected to each other by reflowing the solder balls 40. This is because the semiconductor element 30 having already and electrically been connected to the lower layer side wiring board 10 is electrically connected to the upper layer side wiring board 20 through the solder balls 40.

More specifically, the lower layer side wiring board 10 and the upper layer side wiring board 20 are connected to each other through components from the bump 14 formed on the lower layer side wiring board 10, the connection portion 12b formed on the top surface of the lower layer side wiring board 10, the first electrode 32 of the semiconductor element 30, the solder ball electrode 34, and the solder balls 40, to the connection portion 22 provided on the upper layer side wiring board 20.

The gap between the lower layer side wiring board 10 and the upper layer side wiring board 20 is sealed with a seal resin 50 such as an epoxy resin.

Incidentally, circuit components 16 can be mounted between the lower layer side wiring board 10 and the upper layer side wiring board 20, in addition to the semiconductor elements 30.

Next, a method for manufacturing an electronic component built-in substrate 100 according to the present embodiment is described below. FIGS. 2 to 6 are transverse cross-sectional views illustrating states in steps of a process of manufacturing an electronic component built-in substrate.

First, as illustrated in FIG. 2, the semiconductor element 30 serving as an electronic component is connected to the connection portion 12b formed on the top surface of the lower layer side wiring board 10 serving as a first board through the flip-chip connection bump 36. The wiring or each of the connection portions 12a and 12b is preliminarily formed on the lower layer side wiring board 10.

Next, as illustrated in FIG. 3, the solder balls 40 are mounted on the solder ball electrode 34 that is provided on the top surface of the semiconductor element 30. The solder balls 40 may be connected to the bottom surface of the upper layer side wiring board 20. Incidentally, in a case where the circuit components 16 are mounted between the lower layer wiring board 10 and the upper layer side wiring board 20, the circuit components 16 are mounted therebetween at this stage.

Next, as illustrated in FIG. 4, the connection portion 22 provided on the side of the bottom surface of the upper layer side wiring board 20 serving as a second board, which is formed separately from the lower layer side wiring board 10, is positioned at and is placed on the solder ball 40 (i.e., is mounted thereon so as to face the top surface of the lower layer side wiring board 10). Then, the solder ball 40 is reflowed. Subsequently, the lower layer side wiring board 10 is electrically connected to the upper layer side wiring board 20. After the solder balls 40 are reflowed, stains such as fluxes, adhering to the top surface of the lower layer side wiring board 10, the bottom surface of the upper layer side wiring board 20, and the surfaces of the semiconductor element 30 are cleaned. Upon completion of cleaning the stains, as illustrated in FIG. 5, a seal resin 50, such as an epoxy resin, is injected into the gap between the lower layer side wiring board 10 and the upper layer side wiring board 20.

Then, as illustrated in FIG. 6, the circuit components 16, such as chip capacitors and resistors, are attached to the top surface of the upper layer side board 20 by soldering. Additionally, the bump 14 made of a material such as solder is provided on the connection portion 12a, which is formed by exposing a part of the wiring provided on the bottom surface of the lower layer side wiring board 10. Thus, the electronic component built-in substrate 100 is completed.

Necessity for peripheral areas of the electronic component 30, which are used for providing the solder balls 40 in the electronic component built-in substrate 100, is eliminated by utilizing an empty area in the top surface (i.e., a surface facing a flip-chip connected surface) of the semiconductor element 30 serving as an electronic component, as described above. It is sufficient for the solder ball 40 to have a diameter dimension enough to connect the top surface of the semiconductor element 30 to the bottom surface of the upper layer wiring board 20. Consequently, a pitch, at which the solder balls 40 are provided, can be set at a small value. Accordingly, the planar dimension (i.e., the plane area) of the electronic component built-in substrate 100 can considerably be reduced. Also, even in the case of high density wiring pattern, the electric connection among the boards, the parts, and the components can easily be performed.

Additionally, the diameter dimension of each of the solder balls is reduced to a small value. Thus, the thickness dimension of the electronic component built-in substrate 100 can be decreased.

As a result of reducing the diameter dimension of each of the solder balls 40 to a small diameter dimension, many solder balls 40 can be provided in the plane area of the semiconductor element 30. Also, a high-performance compact electronic component built-in substrate 100 can easily be manufactured.

### Second Embodiment

FIG. 7 is a transverse cross-sectional view illustrating the structure of an electronic component built-in substrate according to a second embodiment of the invention. FIG. 8 is a schematic view illustrating the structure of a wire bonding portion between an electronic component and a board.

In the present embodiment, the semiconductor element 30 serving as an electronic component mounted on the top surface of the lower layer side wiring board 10 serving as a first wiring features that the first electrode 32 and the second electrode 34 are formed on the same surface, and that the semiconductor element 30 is electrically connected to the bonding pad 12c of the lower layer side wiring board 10 by a bonding wire 60. The bonding pad 12c serving as the top-surface side connection portion formed on the lower layer side wiring board 10 is connected to a wire-bonding electrode 32 (corresponding to the first electrode) by a gold wire serving as the bonding wire 60. A part of the wire bonding electrode 32 and a part of the solder ball electrode 34 are electrically connected to each other.

The bonding pad 12c provided in the lower layer side wiring board 10 is formed by performing gold-plating on a copper pad. It is frequent that the wire bonding electrode 32 is made of aluminum. Thus, in the case of employing a manner of electrically connecting the semiconductor element 30 to the lower layer side wiring board 10 by wire-bonding, it is necessary to protect the bonding wire 60 from bending and breaking during the electronic component built-in substrate 100 is manufactured and processed. Also, it is necessary to protect the electronic component built-in substrate 100 during the flux is cleaned after the solder balls 40 are reflowed.

Chemicals, such as acids, are sometimes used for cleaning the stain such as the flux. There is a high risk that when using an acid, the wire bonding electrode 32 of the semiconductor element 30 made of aluminum is damaged by the acid so that the reliability of the electrical connection between the bonding wire 60 and the wire bonding electrode 32 is degraded. The solder ball electrode 34 is covered with molten solder 44 obtained by reflowing the solder balls 40. Accordingly, there is no fear of degradation of the reliability of the electrical connection due to the cleaning of the stain.

Thus, according to the present embodiment, upon completion of wire-bonding between the bonding electrode 32 of the semiconductor element 30 and the bonding pad 12c of the lower layer side wiring board 10, the wire bonding electrode 32 is coated with a resin 70 serving as the protection material. As illustrated in FIGS. 7 and 8, the resin 70 is dropped thereto by potting, so as to cover the wire bonding electrode 32 provided on the top surface of the semiconductor element 30. According to the present embodiment, the wire-bonding electrode 32 is coated with the resin 70 in a state in which the connection portion between the top end surface portion (i.e., the top-most portion) of the bonding-wire 60 and the bonding pad 12c of the lower layer side wiring board 10 is exposed.

Additionally, the resin 70 covering the wire-bonding electrode 32 of the semiconductor element 30 has a resistance to chemicals used for cleaning the flux. Consequently, the reliability of the electrical connection between the wire bonding electrode 32 and the bonding wire 60 is prevented from being degraded. Additionally, the resin 70 serving as the protection material covers only a minimum range including the wire bonding electrode 32 of the electronic component 30. Thus, most of the top surface of the semiconductor element 30, which is not coated with the resin 70, can be used as an area on which the solder balls 40 are mounted.

Also, in the present embodiment, the height position of the top end of a wire loop formed of the bonding wire 60 is higher than that of the top surface of the semiconductor element 30. Thus, a minimum value of the diameter dimension of each of the solder balls 40 is constrained by the height position of the top surface of the semiconductor element 30 and that of the top of the wire loop. Even under such constraint, the diameter dimension of the solder balls 40 according to the present embodiment of the invention can be reduced to a value smaller than that of solder balls used in related art substrates. Also, the planar dimension of the electronic component built-in substrate 100 can be reduced to a small value. Additionally, the thickness of the substrate can be decreased.

### Third Embodiment

FIG. 9 is a transverse cross-section illustrating the structure of an electronic component built-in substrate according to a third embodiment of the invention. The present embodiment is an electronic component built-in substrate 100 configured so that semiconductor elements 30 and 31 serving as electronic components are arranged between the lower layer side wiring board 10 acting as the first wiring board and the upper layer wiring board 20 acting as the second wiring board. The first semiconductor element 30 is mounted on the top surface of the lower layer wiring board 10. The second semiconductor element 31, which is smaller in the plane area than the first semiconductor element 30, is mounted on the first semiconductor element 30. Both the first semiconductor element 30 and the second semiconductor element 31 are electrically connected to the bonding pad 12c serving as the connection portion of the lower layer side wiring board 10, by wire-bonding.

The first semiconductor element 30 is configured so that a wire bonding electrode 32a and the bonding pad 12c of the lower layer side wiring board 10 are electrically connected to each other by the bonding wire 60. After one of the wire bonding electrode 32a of the first semiconductor element 30 and the bonding pad 12c of the lower layer side wiring board 10 is appropriately selected, the second semiconductor element 31 can be electrically connected to the selected electrode or pad, using the bonding wire 60 connected to a wire bonding electrode 32b. The second semiconductor element 31 is configured so that a part of the wire bonding electrode 32b and a part of the solder ball electrode 34 are electrically connected to each other.

In a case where the wire bonding electrodes 32a and 32b respectively provided on the semiconductor elements 30 and 31 are made of aluminum, a minimum portion including the wire bonding electrodes 32a and 32b is coated with the resin 70. Thus, even when the flux is cleaned after the solder balls 40 are reflowed, the reliability of the electrical connection at each of the wire bonding electrodes 32a and 32b can be maintained. Although the solder ball electrode 34 is made of aluminum, this electrode is covered with the solder obtained by reflowing the solder ball 40. Consequently, the protection material is unnecessary for the solder ball electrode 34.

The solder ball electrode 34 is provided on the top surface of the second semiconductor element 31, which is provided as a top stage of the arranged semiconductor elements. The solder balls 40 are placed on the solder ball electrode 34. The configuration of the solder balls 40 is similar to that described above. After the solder balls 40 are reflowed, the fluxes adhering to the opposed surfaces of the lower layer side wiring board 10 and the upper layer side wiring board 20 and the surfaces of the semiconductor elements 30 and 31 are cleaned. Subsequently, a seal resin 50, such as an epoxy resin, is injected into the gap between the lower layer side wiring board 10 and the upper layer side wiring board 20. Thus, the electronic component built-in substrate 100 is completed.

### Fourth Embodiment

FIG. 10 is a transverse cross-sectional view illustrating the structure of an electronic component built-in substrate according to a fourth embodiment of the invention. The fourth embodiment is similar to the third embodiment in that a plurality of a first semiconductor element 30 and a second semiconductor element 31 serving as a plurality of electronic components are arranged between a lower layer side wiring board 10 and an upper layer side wiring board 20. However, the fourth embodiment differs from the first and second embodiments in that the first semiconductor element 30 provided under the second semiconductor element 31 is flip-chip connected to a connection portion 12b of the lower layer side wiring board 10, while the second semiconductor element 31 provided on the first semiconductor element 30 is wire-bonded to the bonding pad 12c of the lower layer side wiring board 10.

Also, in the fourth embodiment, a wire bonding electrode 32b provided on the top surface of the second semiconductor element 31 is made of gold.

Even in the present embodiment, the solder balls 40 are provided on the solder ball electrode 34 that is provided on the top surface of the second semiconductor element 31. Subsequently, the solder balls 40 are reflowed. However, because the wire bonding-electrode 32b is made of gold, favorably, the reliability of the electrical connection at the wire bonding electrode 32b can be prevented, without coating the wire bonding electrode 32b with a resin 70 serving as the protection material, from being degraded by a cleaner such as an acid. The numbered remaining members are similar to the associated members of the aforementioned embodiments.

In the foregoing description, the electronic component built-in substrates according to the invention have been described in detail, based on the foregoing description of the embodiments, the invention is not limited to the aforementioned embodiments. Apparently, various modifications made without departing from the spirit of the invention are included within the scope of the invention. For example, although semiconductor elements have been described as examples of electronic components in the foregoing description of the embodiments, the electronic components are not limited to the semiconductor elements. Apparently, other electronic components can be employed.

Although the embodiment employing the copper core 42 as a core member of each of the solder balls 40 has been described above, core members obtained by forming various electrically conductive materials, such as a metal, into spherical bodies can be employed as the core member of the solder ball 40, instead of the copper core obtained by forming copper into a spherical body. In a case where an amount of the solder 44 covering an outer surface of the core member is sufficient to also cover the solder ball electrode 34 and to establish the electrical connection, an insulating member obtained by forming a resin material into a spherical body can be employed as the core member, instead of the electrically conductive member.

Although the first semiconductor element 30 and the second semiconductor element 31 serving as electronic components have been described as arranged two layers (see FIGS. 9 and 10) in the descriptions of the third and fourth embodiments, the invention can employ a structure in which the second semiconductor element 31 is employed as a dummy chip used only for placing the solder balls 40 thereon. In the case of employing such a dummy chip, the electrical connection can be established between the dummy chip and the lower layer side wiring board 10 serving as the first board by the bonding wire 60. In a case where the wire bonding electrode 32b of the dummy chip is made of gold, it is unnecessary to coat the wire bonding electrode 32b with the resin 70 serving as the protection material. However, in a case where the wire bonding electrode 32b is made of aluminum, apparently, it is necessary to coat the wire bonding electrode 32b with the resin 70 serving as the protection material. The range coated with the resin is similar to that employed in the aforementioned embodiment.

Additionally, a semiconductor package of what is called a PoP (Package-on-Package) structure, in which a plurality of electronic component built-in substrates 100 each containing semiconductor elements 30 between the lower layer side wiring board 10 and the upper layer side wiring board 20 are arranged and are electrically connected to one another, can be employed as the electronic component, instead of the semiconductor element 30.

In the foregoing description of the method for manufacturing the electronic component built-in substrate 100, the step of forming the bump 14 on the bottom surface of the lower layer side wiring board 10 has been described as a final step. However, the step of forming the bump 14 on the bottom surface of the lower layer side wiring board 10 can appropriately be moved to another part of the method for manufacturing the electronic component built-in substrate 100, without hindering the other steps.

What is claimed is:

1. An electronic component built-in substrate comprising:
at least two wiring boards,
an electronic component provided between the two wiring boards,
an electrode of the electronic component,
the electrode being electrically connected to at least one of the wiring boards, the wiring boards being electrically connected to each other, and a gap between the wiring boards being sealed with a resin, and
a solder ball for electrically connecting the wiring boards to each other, the solder ball being provided on a surface of the electronic component which faces the other wiring board.

2. The electronic component built-in substrate according to claim 1, wherein
the solder ball is a core-contained solder ball formed by coating an outer surface of a metal sphere with solder.

3. The electronic component built-in substrate according to claim 1, wherein
the solder ball is a copper-contained solder ball formed by coating an outer surface of a sphere made of copper material with solder.

4. The electronic component built-in substrate according to claim 1, wherein
a plurality of the electronic components are provided between the wiring boards.

5. The electronic component built-in substrate according to claim 1, wherein
at least one of electrodes of the electronic component is wire-bonded to the one of the wiring boards.

6. The electronic component built-in substrate according to claim 5, wherein
at least the wire-bonded electrode in the electrodes of the electronic component is coated with a protection material.

7. The electronic component built-in substrate according to claim 6, wherein
the protection material is coated on at least the electrode of the electronic component in a state in which a bonding wire connection portion at the side of the wiring board and a part of an upper-side portion of a wire loop formed of the bonding wire are exposed.

8. A method for manufacturing an electronic component built-in substrate wherein an electronic component is mounted between a first wiring board and a second wiring board, the first wiring board and the second wiring board are electrically connected to each other, and a seal resin is injected into a gap between the first wiring board and the second wiring board,
the method comprising the steps of:
positioning and mounting the electronic component provided with a plurality of electrodes on one surface of the first wiring board, and electrically connecting a first electrode of the electronic component to the first wiring board,
connecting a solder ball to a second electrode of the electronic component,
opposing one surface of the second wiring board to the solder ball connected to the second electrode of the electronic component, and arranging the second wiring board on the first wiring board,
electrically connecting the second wiring board to the electronic component by reflowing the solder balls to electrically connect the first wiring board to the second wiring board through the electronic component, and
injecting a seal resin into a gap between the first wiring board and the second wiring board.

9. A method for manufacturing an electronic component built-in substrate wherein an electronic component is mounted between a first wiring board and a second wiring board, the first wiring board and the second wiring board are electrically connected to each other, and a seal resin is injected into a gap between the first wiring board and the second wiring board,
the method comprising the steps of:
positioning and mounting the electronic component provided with a plurality of electrodes on one surface of the first wiring board, and electrically connecting a first electrode of the electronic component to the first wiring board,
connecting a solder ball to one surface of the second wiring board,
opposing one surface of the second wiring board to the solder ball connected to the second electrode of the electronic component, and arranging the second wiring board on the first wiring board,
electrically connecting the second wiring board to the electronic component by reflowing the solder balls to electrically connect the first wiring board to the second wiring board through the electronic component, and
injecting a seal resin into a gap between the first wiring board and the second wiring board.

10. The method for manufacturing an electronic component built-in substrate according to claim 8, wherein
as the solder ball, a core-contained solder ball formed by coating an outer surface of a metal spherical core member with solder is used.

11. The method for manufacturing an electronic component built-in substrate according to claim 8, wherein
as the solder ball, a core-contained solder ball formed by coating an outer surface of a copper spherical core member with solder is used.

12. The method for manufacturing an electronic component built-in substrate according to claim 8, wherein
the first electrode like a bump is formed on one surface of the electronic component, while the second electrode is formed on another surface of the electronic component, and
the first electrode is electrically connected to the first wiring board by a flip chip method using the first electrode.

13. The method for manufacturing an electronic component built-in substrate according to claim 8, wherein
the first electrode and the second electrode of the electronic component are formed on a same surface thereof, and
the step of electrically connecting the first electrode to the first wiring board is performed by a wire bonding connection.

14. The method for manufacturing an electronic component built-in substrate according to claim 9, wherein
as the solder ball, a core-contained solder ball formed by coating an outer surface of a metal spherical core member with solder is used.

15. The method for manufacturing an electronic component built-in substrate according to claim 9, wherein
as the solder ball, a core-contained solder ball formed by coating an outer surface of a copper spherical core member with solder is used.

16. The method for manufacturing an electronic component built-in substrate according to claim 9, wherein
the first electrode like a bump is formed on one surface of the electronic component, while the second electrode is formed on another surface of the electronic component, and
the first electrode is electrically connected to the first wiring board by a flip chip method using the first electrode.

17. The method for manufacturing an electronic component built-in substrate according to claim 9, wherein
the first electrode and the second electrode of the electronic component are formed on a same surface thereof, and
the step of electrically connecting the first electrode to the first wiring board is performed by a wire bonding connection.
